(19) United States
(12) Patent Application Publication
(10) Pub. No.: US 2026/0215336 A1
(43) Pub. Date: Jul. 23, 2026

(54) MEMORY DEVICES AND MEMORY SYSTEMS FOR STABILIZING VOLTAGES

(71) Applicant: SK hynix Inc., Icheon-si Gyeonggi-do (KR)

(72) Inventors: Boo Ho JUNG, Icheon-si Gyeonggi-do (KR); Seung Hoon HONG, Icheon-si Gyeonggi-do (KR)

(73) Assignee: SK hynix Inc., Icheon-si Gyeonggi-do (KR)

(21) Appl. No.: 19/232,336

(22) Filed: Jun. 9, 2025

(30) Foreign Application Priority Data
Jan. 23, 2025 (KR) 10-2025-0010738

(51) Int. Cl. H01L 25/18; H01L 23/00; H01L 23/48; H01L 23/64; H01L 25/065; H10B 80/00; H10D 80/30

(52) U.S. Cl. CPC H10W 90/00; H10B 80/00; H10D 80/30; H10W 20/20; H10W 44/601; H10W 90/293; H10W 90/297; H10W 90/752

(57) ABSTRACT

A memory device includes a base die disposed over a substrate, a plurality of core dies disposed over the base die, and a power die disposed over the core dies. The base die, the core dies, and the power die are connected to each other using through-vias. The power die includes a coupling device that keeps a power supply voltage supplied through the through-vias within a set voltage range.

### CROSS-REFERENCE TO RELATED APPLICATIONS

The present application claims priority under 35 U.S.C § 119(a) to Korean Application No. 10-2025-0010738, filed in the Korean Intellectual Property Office on Jan. 23, 2025, the entire contents of which application is incorporated herein by reference.

### BACKGROUND

### 1. Technical Field

The present disclosure generally relates to memory devices, and more particularly, to memory devices and memory systems that include voltages that are maintained within a set voltage range.

### 2. Related Art

Stack memory systems such as high bandwidth memory (HBM) devices have been used in a wide range of applications due to their high bandwidth. Unlike conventional memory system that uses parallel data bus, the stack memory system includes a stack memory device including a base die and core dies interconnected by through silicon vias (TSVs). The stack memory device includes a physical interface such as a physical layer for communication with a processor. The physical layer is designed for high speed data transmission and efficient communication.

### SUMMARY

The present disclosure, in an embodiment, describes a memory device that may include a base die disposed over a substrate, a plurality of core dies disposed over the base die, and a power die disposed over the plurality of core dies. The base die, the plurality of core dies, and the power die may be connected to each other using through-vias, and the power die may include a coupling device that keeps a power supply voltage supplied through the through-vias within a set voltage range.

The present disclosure, in an embodiment, describes a memory device that may include a plurality of core dies disposed over a base die and a power die disposed over the plurality of core dies. The base die, the plurality of core dies, and the power die may be connected to each other using through-vias, and the power die may include a coupling device that keeps an internal voltage supplied through the through-vias within a set voltage range.

The present disclosure, in an embodiment, describes a memory device that may include a first core die group disposed over a base die, a first power die disposed over the first core die group, a second core die group disposed over the first power die, and a second power die disposed over the second core die group. The base die, the first core die group, the first power die, the second core die group, and the second power die may be connected to each other using through-vias, and each of the first power die and the second power die may include a coupling device that keeps a power supply voltage supplied through the through-vias within a set voltage range.

The present disclosure, in an embodiment, describes a memory device that may include a first core die group disposed over a base die, a first power die disposed over the first core die group, a second core die group disposed over the first power die, and a second power die disposed over the second core die group. The base die, the first core die group, the first power die, the second core die group, and the second power die may be connected to each other using through-vias, and each of the first power die and the second power die may include a coupling device that keeps an internal voltage supplied through the through-vias within a set voltage range.

The present disclosure, in an embodiment, describes a memory device that may include a first core die group disposed over a base die, a first power die disposed over the first core die group, a second core die group disposed over the first power die, a second power die disposed over the second core die group, a first transmission circuit connected between the base die and the first power die to supply a power supply voltage, and a second transmission circuit connected between the base die and the second power die to be connected to a ground voltage. The base die, the first core die group, the first power die, the second core die group, and the second power die may be connected to each other using through-vias, and each of the first power die and the second power die may include a coupling device that keeps the power supply voltage supplied through the through-vias within a set voltage range.

The present disclosure, in an embodiment, describes a memory device that may include a first core die group disposed over a base die, a first power die disposed over the first core die group, a second core die group disposed over the first power die, a second power die disposed over the second core die group, a first transmission circuit connected between the base die and the first power die to supply an internal voltage, and a second transmission circuit connected between the base die and the second power die to be connected to a ground voltage. The base die, the first core die group, the first power die, the second core die group, and the second power die may be connected to each other using through-vias, and each of the first power die and the second power die may include a coupling device that keeps the internal voltage supplied through the through-vias or the first transmission circuit within a set voltage range.

The present disclosure, in an embodiment, describes a memory device that may include a first core die group disposed over a base die, a first power die disposed over the first core die group, a second core die group disposed over the first power die, a second power die disposed over the second core die group, a first bonding wire connected between the base die and the first power die to supply a power supply voltage, and a second bonding wire connected between the base die and the second power die to be connected to a ground voltage. The base die, the first core die group, the first power die, the second core die group, and the second power die may be connected to each other using through-vias, and each of the first power die and the second power die may include a coupling device that keeps the power supply voltage supplied through the through-vias or the first transmission circuit within a set voltage range.

The present disclosure, in an embodiment, describes a memory device that may include a first core die group disposed over a base die, a first power die disposed over the first core die group, a second core die group disposed over the first power die, a second power die disposed over the second core die group, a first bonding wire connected between the base die and the first power die to supply an internal voltage, and a second bonding wire connected between the base die and the second power die to be connected to a ground voltage The base die, the first core die group, the first power die, the second core die group, and the second power die may be connected to each other using through-vias, and each of the first power die and the second power die may include a coupling device that keeps the internal voltage supplied through the through-vias or the first bonding wire within a set voltage range.

The present disclosure, in an embodiment, describes a memory system that may include a processor and a memory device disposed over an interposer. The memory device may include a core die structure including a plurality of core dies stacked over a base die and at least one power die including a coupling device that keeps a power supply voltage or an internal voltage supplied to each of the plurality of core dies within a set voltage range.

### BRIEF DESCRIPTION OF THE DRAWINGS

FIG. 1 illustrates a memory device according to an embodiment of the present disclosure.

FIG. 2 illustrates a power die included in a memory device according to an embodiment of the present disclosure.

FIG. 3 illustrates a memory device according to an embodiment of the present disclosure.

FIG. 4 illustrates a power die included in a memory device according to an embodiment of the present disclosure.

FIG. 5 illustrates a memory device according to an embodiment of the present disclosure.

FIG. 6 illustrates power dies included in a memory device according to an embodiment of the present disclosure.

FIG. 7 illustrates a memory device according to an embodiment of the present disclosure.

FIG. 8 illustrates power dies included in a memory device according to an embodiment of the present disclosure.

FIG. 9 illustrates a memory device according to an embodiment of the present disclosure.

FIG. 10 illustrates power dies included in a memory device according to an embodiment of the present disclosure.

FIG. 11 illustrates a memory device according to an embodiment of the present disclosure.

FIG. 12 illustrates power dies included in the memory device according to an embodiment of the present disclosure.

FIG. 13 illustrates a memory device according to an embodiment of the present disclosure.

FIG. 14 illustrates power dies included in the memory device according to an embodiment of the present disclosure.

FIG. 15 illustrates a memory device according to an embodiment of the present disclosure.

FIG. 16 illustrates power dies included in the memory device according to an embodiment of the present disclosure.

FIG. 17, FIG. 18, and FIG. 19 illustrate equivalent circuits of memory devices according to an embodiment of the present disclosure.

FIG. 20 illustrates waveforms of a power supply voltage and an internal voltage stabilized by power dies provided in a memory device according to an embodiment of the present disclosure.

FIG. 21 illustrates a memory system according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various devices and do not imply size, order, priority, quantity, or importance of the devices. For example, a first device may be named as a second device in one example, and the second device may be named as a first device in another example.

When one component is identified as “connected” to another component, the components may be connected directly or through an intervening component between the components. When two components are identified as “directly connected,” one component is directly connected to the other component without an intervening component between the two components. As used herein, the term “and/or” includes any and all combinations of one or more of the associated listed items.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

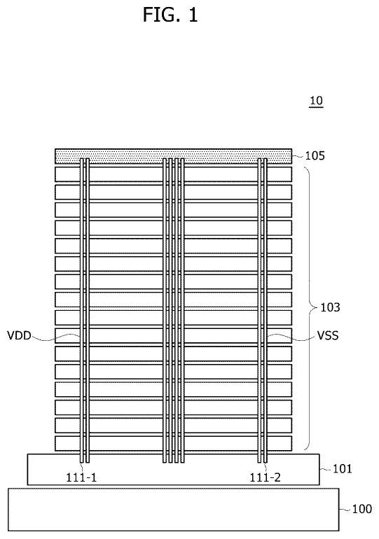

FIG. 1 illustrates a memory device 10 according to an embodiment of the present disclosure.

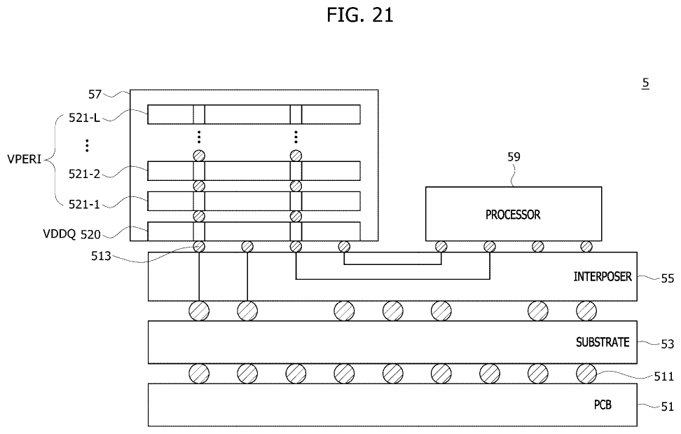

As illustrated in FIG. 1, the memory device 10 includes a substrate 100, a plurality of core dies 103, and a power die 105. The substrate 100 functions as a physical base for a printed circuit board, for example, a printed circuit board (PCB) 51 in FIG. 21 and is an insulator. The substrate 100 may include materials such as flame retardant, class 4, FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like. The base die 101 is disposed over the substrate 100. The plurality of core dies 103 are stacked over the base die 101, and the power die 105 is stacked over the plurality of core dies 103.

Each of the core dies 103 exchanges data with a processor, for example, a processor 59 in FIG. 21 under control of the base die 101. Each of the core dies 103 includes a memory cell array that stores data. The data stored in the memory cell array of each of the core dies 103 is transmitted to the processor under the control of the base die 101. The data transmitted from the processor is stored in the memory cell array of each of the core dies 103 under the control of the base die 101.

The power die 105 stabilizes a power supply voltage VDD supplied to the core dies 103 through the base die 101. More specifically, the power die 105 includes a plurality of wires and a plurality of capacitors to stabilize the power supply voltage VDD. For example, the power die 105 maintains the power supply voltage VDD supplied to the core dies 103 through the base die 101 within a set voltage range and/or set voltage level. More specifically, the power die 105 includes a plurality of wires and a plurality of capacitors to assist in keeping the power supply voltage VDD within a set voltage range, and/or not exceed the set voltage range.

The base die 101, the core dies 103, and the power die 105 are connected using through-vias and transmit and receive signals using the through-vias. The signals transmitted and received by each of the base die 101, the core dies 103, and the power die 105 using the through-vias include data, commands, addresses, and the like.

The core dies 103 and the power die 105 are supplied with the power supply voltage VDD of the base die 101 and are connected to a ground voltage VSS of the base die 101 using the through-vias, for example, through-vias 111-1 and 111-2. The base die 101 receives the power supply voltage VDD and is connected to the ground voltage VSS through the substrate 100.

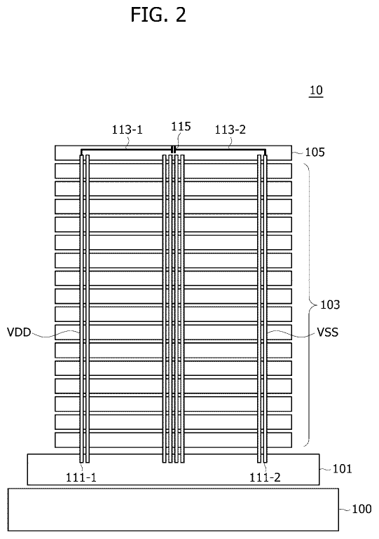

FIG. 2 illustrates a power die 105 included in a memory device according to an embodiment of the present disclosure, for example, as illustrated in FIG. 1.

As illustrated in FIG. 2, the power die 105 includes a first wire 113-1, a second wire 113-2, and a capacitor 115. The first wire 113-1 is electrically connected to the first through-via 111-1 through which the power supply voltage VDD of the base die 101 is supplied. The second wire 113-2 is electrically connected to the second through-via 111-2 to which the ground voltage VSS of the base die 101 is connected. The capacitor 115 is electrically connected between the first wire 113-1 and the second wire 113-2. The capacitor 115 is electrically connected to the first through-via 111-1 through which the power supply voltage VDD is supplied through the first wire 113-1, and is electrically connected to the second through-via 111-2 to which the ground voltage VSS is connected through the second wire 113-2 to operate as a coupling device. The capacitor 115 prevents or mitigates a voltage level of the power supply voltage VDD from rapidly fluctuating to maintain the voltage level of the power supply voltage VDD stably. In an embodiment, the capacitor 115 prevents or mitigates a voltage level of the power supply voltage VDD from rapidly fluctuating to maintain the voltage level of the power supply voltage VDD within a set voltage range, and/or not exceed the set voltage range.

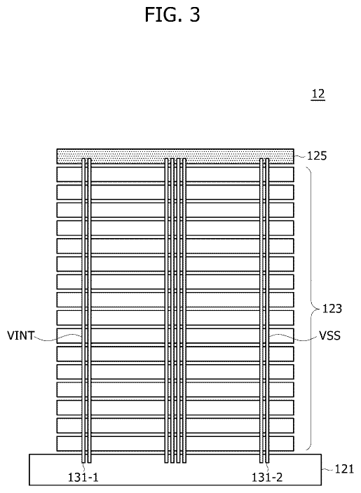

FIG. 3 illustrates a memory device 12 according to an embodiment of the present disclosure.

As illustrated in FIG. 3, the memory device 12 includes a base die 121, a plurality of core dies 123, and a power die 125. The plurality of core dies 103 are stacked over the base die 121, and the power die 125 is stacked over the plurality of core dies 123.

Each of the core dies 123 exchanges data with a processor, for example, a processor 59 in FIG. 21 under control of the base die 121. Each of the core dies 123 includes a memory cell array that stores data. The data stored in the memory cell array of each of the core dies 123 is transmitted to the processor under the control of the base die 121. The data transmitted from the processor is stored in the memory cell array of each of the core dies 123 under the control of the base die 121.

The power die 125 stabilizes an internal voltage VINT supplied to the core dies 123. More specifically, the power die 125 includes a plurality of wires and a plurality of capacitors to stabilize the internal voltage VINT. For example, the power die 125 maintains the internal voltage VINT supplied to the core dies 123 a set voltage range and/or set voltage level. More specifically, the power die 125 includes a plurality of wires and a plurality of capacitors to assist in keeping the internal voltage VINT within a set voltage range, and/or not exceed the set voltage range.

The base die 121, the core dies 123, and the power die 125 are connected using through-vias and transmit and receive signals using the through-vias. The signals transmitted and received by each of the base die 121, the core dies 123, and the power die 125 using the through-vias include data, commands, addresses, and the like.

The core dies 123 and the power die 125 are supplied with the internal voltage VINT generated in the base die 121 or the core dies 123 and are connected to a ground voltage VSS of the base die 121 using the through-vias, for example, through-vias 131-1 and 131-2.

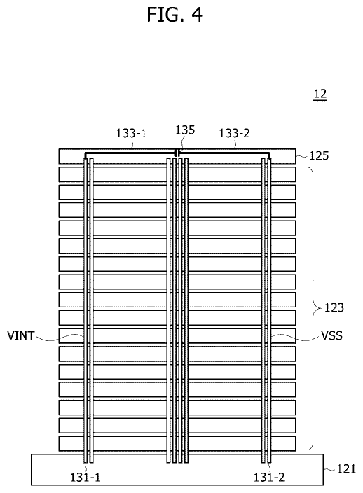

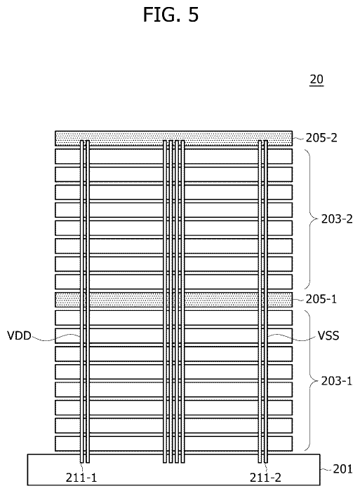

FIG. 4 illustrates a power die 125 included in a memory device according to an embodiment of the present disclosure, for example, as illustrated in FIG. 3.

As illustrated in FIG. 4, the power die 125 includes a first wire 133-1, a second wire 133-2, and a capacitor 135. The first wire 133-1 is electrically connected to the first through-via 131-1 through which an internal voltage VINT generated in the base die 121 or the core dies 123 is supplied. The second wire 133-2 is electrically connected to the second through-via 131-2 to which the ground voltage VSS of the base die 121 is connected. The capacitor 135 is electrically connected between the first wire 133-1 and the second wire 133-2. The capacitor 135 is electrically connected to the first through-via 131-1 through which the internal voltage VINT is supplied through the first wire 133-1, and is electrically connected to the second through-via 131-2 to which the ground voltage VSS is connected through the second wire 133-2 to operate as a coupling device. The capacitor 135 prevents or mitigates a voltage level of the internal voltage VINT from rapidly fluctuating to maintain the voltage level of the internal voltage VINT stably. In an embodiment, the capacitor 135 prevents or mitigates a voltage level of the internal voltage VINT from rapidly fluctuating to maintain the voltage level of the internal voltage VINT within a set voltage range, and/or not exceed the set voltage range.

FIG. 5 illustrates a memory device 20 according to an embodiment of the present disclosure.

As illustrated in FIG. 5, the memory device 20 includes a base die 201, a first core die group 203-1, a first power die 205-1, a second core die group 203-2, and a second power die 205-2. The first core die group 203-1 is stacked over the base die 201, the first power die 205-1 is stacked over the first core die group 203-1, the second core die group 203-2 is stacked over the first power die 205-1, and the second power die 205-2 is stacked over the second core die group 203-2. The first power die 205-1 is positioned between the first core die group 203-1 and the second core die group 203-2.

Each core die included in the first core die group 203-1 exchanges data with a processor, for example, a processor 59 in FIG. 21 under control of the base die 201. Each of the core dies included in the first core die group 203-1 includes a memory cell array that stores data. The data stored in the memory cell array of each of the core dies included in the first core die group 203-1 is transmitted to the processor under the control of the base die 201. The data transmitted from the processor is stored in the memory cell array of each of the core dies included in the first core die group 203-1 under the control of the base die 121.

The first power die 205-1 stabilizes a power supply voltage VDD supplied to the first core die group 203-1 and the second core die group 203-2. More specifically, the first power die 205-1 includes a plurality of wires and a plurality of capacitors to stabilize the power supply voltage VDD. For example, the first power die 205-1 maintains the power supply voltage VDD supplied to the first core die group 203-1 and the second core die group 203-2 a set voltage range and/or set voltage level. More specifically, the first power die 205-1 includes a plurality of wires and a plurality of capacitors to assist in keeping the power supply voltage VDD within a set voltage range, and/or not exceed the set voltage range.

Each of the core dies included in the second core die group 203-2 exchanges data with a processor, for example, the processor 59 in FIG. 21 under the control of the base die 201. Each of the core dies included in the second core die group 203-2 includes a memory cell array that stores data. The data stored in the memory cell array of each of the core dies included in the second core die group 203-2 is transmitted to the processor under the control of the base die 201. The data transmitted from the processor is stored in the memory cell array of each of the core dies included in the second core die group 203-2 under the control of the base die 201.

The second power die 205-2 stabilizes the power supply voltage VDD supplied to the first core die group 203-1 and the second core die group 203-2. More specifically, the second power die 205-2 includes a plurality of wires and a plurality of capacitors to stabilize the power supply voltage VDD. For example, the second power die 205-2 maintains the power supply voltage VDD supplied to the first core die group 203-1 and the second core die group 203-2 a set voltage range and/or set voltage level. More specifically, the second power die 205-2 includes a plurality of wires and a plurality of capacitors to assist in keeping the power supply voltage VDD within a set voltage range, and/or not exceed the set voltage range.

The base die 201, the first core die group 203-1, the first power die 205-1, the second core die group 203-2, and the second power die 205-2 are connected using through-vias and transmit and receive signals using the through-vias. The signals transmitted and received by each of the base die 201, the first core die group 203-1, the first power die 205-1, the second core die group 203-2, and the second power die 205-2 using the through-vias include data, commands, addresses, and the like.

The first core die group 203-1, the first power die 205-1, the second core die group 203-2, and the second power die 205-2 are supplied with the power supply voltage VDD of the base die 201, and are connected to a ground voltage VSS of the base die 201 using the through-vias, for example, through-vias 211-1 and 211-2.

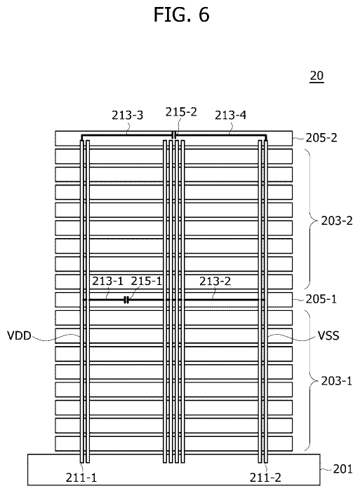

FIG. 6 illustrates a first power die 205-1 and a second power die 205-2 included in a memory device according to an embodiment of the present disclosure, for example, as illustrated in FIG. 5.

As illustrated in FIG. 6, the first power die 205-1 includes a first wire 213-1, a second wire 213-2, and a first capacitor 215-1. The first wire 213-1 is electrically connected to the first through-via 211-1 through which the power supply voltage VDD of the base die 201 is supplied. The second wire 213-2 is electrically connected to the second through-via 211-2 to which the ground voltage VSS of the base die 201 is connected. The first capacitor 215-1 is electrically connected between the first wire 213-1 and the second wire 213-2. The first capacitor 215-1 is electrically connected to the first through-via 211-1 through which the power supply voltage VDD is supplied through the first wire 213-1, and is electrically connected to the second through-via 211-2 to which the ground voltage VSS is connected through the second wire 213-2 to operate as a coupling device. The first capacitor 215-1 prevents or mitigates a voltage level of the power supply voltage VDD from rapidly fluctuating to maintain the voltage level of the power supply voltage VDD stably. In an embodiment, the first capacitor 215-1 prevents or mitigates a voltage level of the power supply voltage VDD from rapidly fluctuating to maintain the voltage level of the power supply voltage VDD within a set voltage range, and/or not exceed the set voltage range.

As illustrated in FIG. 6, the second power die 205-2 includes a third wire 213-3, a fourth wire 213-4, and a second capacitor 215-2. The third wire 213-3 is electrically connected to the first through-via 211-1 through which the power supply voltage VDD of the base die 201 is supplied. The fourth wire 213-4 is electrically connected to the second through-via 211-2 to which the ground voltage VSS of the base die 201 is connected. The second capacitor 215-2 is electrically connected between the third wire 213-3 and the fourth wire 213-4. The second capacitor 215-2 is electrically connected to the first through-via 211-1 through which the power supply voltage VDD is supplied through the third wire 213-3, and is electrically connected to the second through-via 211-2 to which the ground voltage VSS is connected through the fourth wire 213-4 to operate as a coupling device. The second capacitor 215-2 prevents or mitigates a voltage level of the power supply voltage VDD from rapidly fluctuating to maintain the voltage level of the power supply voltage VDD stably. In an embodiment, the second capacitor 215-2 prevents or mitigates a voltage level of the power supply voltage VDD from rapidly fluctuating to maintain the voltage level of the power supply voltage VDD within a set voltage range, and/or not exceed the set voltage range.

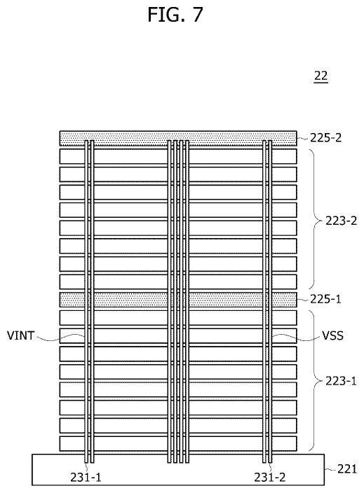

FIG. 7 illustrates a memory device 22 according to an embodiment of the present disclosure.

As illustrated in FIG. 7, the memory device 22 includes a base die 221, a first core die group 223-1, a first power die 225-1, a second core die group 223-2, and a second power die 225-2. The first core die group 223-1 is stacked over the base die 221, the first power die 225-1 is stacked over the first core die group 223-1, the second core die group 223-2 is stacked over the first power die 225-1, and the second power die 225-2 is stacked over the second core die group 223-2. The first power die 225-1 is positioned between the first core die group 223-1 and the second core die group 223-2.

Each core die included in the first core die group 223-1 exchanges data with a processor, for example, a processor 59 in FIG. 21 under control of the base die 221. Each of the core dies included in the first core die group 223-1 includes a memory cell array that stores data. The data stored in the memory cell array of each of the core dies included in the first core die group 223-1 is transmitted to the processor under the control of the base die 221. The data transmitted from the processor is stored in the memory cell array of each of the core dies included in the first core die group 223-1 under the control of the base die 221.

The first power die 225-1 stabilizes an internal voltage VINT supplied to the first core die group 223-1 and the second core die group 223-2. More specifically, the first power die 225-1 includes a plurality of wires and a plurality of capacitors to stabilize the internal voltage VINT. For example, the first power die 225-1 maintains the internal voltage VINT supplied to the first core die group 223-1 and the second core die group 223-2 a set voltage range and/or set voltage level. More specifically, the first power die 225-1 includes a plurality of wires and a plurality of capacitors to assist in keeping the internal voltage VINT within a set voltage range, and/or not exceed the set voltage range.

Each of the core dies included in the second core die group 223-2 exchanges data with the processor under the control of the base die 221. Each of the core dies included in the second core die group 223-2 includes a memory cell array that stores data. The data stored in the memory cell array of each of the core dies included in the second core die group 223-2 is transmitted to the processor under the control of the base die 221. The data transmitted from the processor is stored in the memory cell array of each of the core dies included in the second core die group 223-2 under the control of the base die 221.

The second power die 225-2 stabilizes the internal voltage VINT supplied to the first core die group 223-1 and the second core die group 223-2. More specifically, the second power die 225-2 includes a plurality of wires and a plurality of capacitors to stabilize the internal voltage VINT. For example, the second power die 225-2 maintains the internal voltage VINT supplied to the first core die group 223-1 and the second core die group 223-2 a set voltage range and/or set voltage level. More specifically, the second power die 225-2 includes a plurality of wires and a plurality of capacitors to assist in keeping the internal voltage VINT within a set voltage range, and/or not exceed the set voltage range.

The base die 221, the first core die group 223-1, the first power die 225-1, the second core die group 223-2, and the second power die 225-2 are connected using through-vias and transmit and receive signals using the through-vias. The signals transmitted and received by each of the base die 221, the first core die group 223-1, the first power die 225-1, the second core die group 223-2, and the second power die 225-2 using the through-vias include data, commands, addresses, and the like.

The first core die group 223-1, the first power die 225-1, the second core die group 223-2, and the second power die 225-2 are supplied with the internal voltage VINT generated in one of the base die 221, the first core die group 223-1, and the second core die group 223-2, and are connected to a ground voltage VSS using the through-vias, for example, through-vias 231-1 and 231-2.

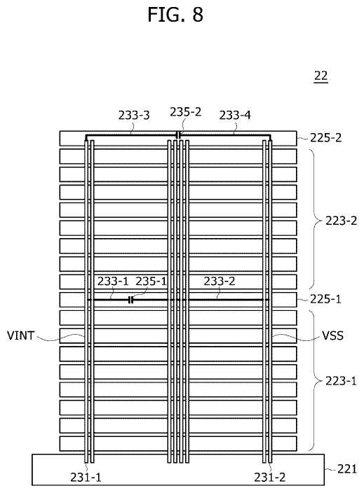

FIG. 8 illustrates a first power die 225-1 and a second power die 225-2 included in a memory device according to an embodiment of the present disclosure, for example, as illustrated in FIG. 7.

As illustrated in FIG. 8, the first power die 225-1 includes a first wire 233-1, a second wire 233-2, and a first capacitor 235-1. The first wire 233-1 is electrically connected to the first through-via 231-1 through which an internal voltage VINT generated in one of the base die 221, the first core die group 223-1, and the second core die group 223-2 is supplied. The second wire 233-2 is electrically connected to the second through-via 231-2 to which the ground voltage VSS of the base die 221 is connected. The first capacitor 235-1 is electrically connected between the first wire 233-1 and the second wire 233-2. The first capacitor 235-1 is electrically connected to the first through-via 231-1 through which the internal voltage VINT is supplied through the first wire 233-1, and is electrically connected to the second through-via 231-2 to which the ground voltage VSS is connected through the second wire 233-2 to operate as a coupling device. The first capacitor 235-1 prevents or mitigates a voltage level of the internal voltage VINT from rapidly fluctuating to maintain the voltage level of the internal voltage VINT stably. In an embodiment, the first capacitor 235-1 prevents or mitigates a voltage level of the internal voltage VINT from rapidly fluctuating to maintain the voltage level of the internal voltage VINT within a set voltage range, and/or not exceed the set voltage range.

As illustrated in FIG. 8, the second power die 225-2 includes a third wire 233-3, a fourth wire 233-4, and a second capacitor 235-2. The third wire 233-3 is electrically connected to the first through-via 231-1 through which the internal voltage VINT is supplied. The fourth wire 233-4 is electrically connected to the second through-via 231-2 to which the ground voltage VSS of the base die 221 is connected. The second capacitor 235-2 is electrically connected between the third wire 233-3 and the fourth wire 233-4. The second capacitor 235-2 is electrically connected to the first through-via 231-1 through which the internal voltage VINT is supplied through the third wire 233-3, and is electrically connected to the second through-via 231-2 to which the ground voltage VSS is connected through the fourth wire 233-4 to operate as a coupling device. The second capacitor 235-2 prevents or mitigates a voltage level of the internal voltage VINT from rapidly fluctuating to maintain the voltage level of the internal voltage VINT stably. In an embodiment, the second capacitor 235-2 prevents or mitigates a voltage level of the internal voltage VINT from rapidly fluctuating to maintain the voltage level of the internal voltage VINT within a set voltage range, and/or not exceed the set voltage range.

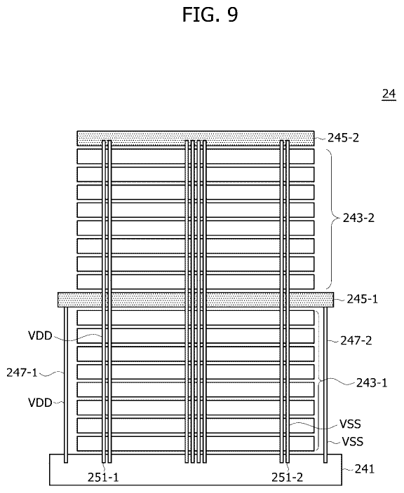

FIG. 9 illustrates a memory device 24 according to an embodiment of the present disclosure.

As illustrated in FIG. 9, the memory device 24 includes a base die 241, a first core die group 243-1, a first power die 245-1, a second core die group 243-2, a second power die 245-2, a first transmission circuit 247-1, and a second transmission circuit 247-2. The first core die group 243-1 is stacked over the base die 241, the first power die 245-1 is stacked over the first core die group 243-1, the second core die group 243-2 is stacked over the first power die 245-1, and the second power die 245-2 is stacked over the second core die group 243-2. The first power die 245-1 is positioned between the first core die group 243-1 and the second core die group 243-2. The first transmission circuit 247-1 electrically connects the base die 241 and the first power die 245-1, and the second transmission circuit 247-2 electrically connects the base die 241 and the first power die 245-1. The first transmission circuit 247-1 and the second transmission circuit 247-2 include a conductive material to which voltage can be supplied or electrically connected.

Each core die included in the first core die group 243-1 exchanges data with a processor, for example, a processor 59 in FIG. 21 under control of the base die 241. Each of the core dies included in the first core die group 243-1 includes a memory cell array that stores data. The data stored in the memory cell array of each of the core dies included in the first core die group 243-1 is transmitted to the processor under the control of the base die 241. The data transmitted from the processor is stored in the memory cell array of each of the core dies included in the first core die group 243-1 under the control of the base die 241.

The first power die 245-1 stabilizes a power supply voltage VDD supplied to the first core die group 243-1 and the second core die group 243-2. More specifically, the first power die 245-1 includes a plurality of wires and a plurality of capacitors to stabilize the power supply voltage VDD. For example, the first power die 245-1 maintains the power supply voltage VDD supplied to the first core die group 243-1 and the second core die group 243-2 a set voltage range and/or set voltage level. More specifically, the first power die 245-1 includes a plurality of wires and a plurality of capacitors to assist in keeping the power supply voltage VDD within a set voltage range, and/or not exceed the set voltage range.

Each core die included in the second core die group 243-2 exchanges data with the processor under the control of the base die 241. Each of the core dies included in the second core die group 243-2 includes a memory cell array that stores data. The data stored in the memory cell array of each of the core dies included in the second core die group 243-2 is transmitted to the processor under the control of the base die 241. The data transmitted from the processor is stored in the memory cell array of each of the core dies included in the second core die group 243-2 under the control of the base die 241.

The second power die 245-2 stabilizes the power supply voltage VDD supplied to the first core die group 243-1 and the second core die group 243-2. More specifically, the second power die 245-2 includes a plurality of wires and a plurality of capacitors to stabilize the power supply voltage VDD. For example, the second power die 245-2 maintains the power supply voltage VDD supplied to the first core die group 243-1 and the second core die group 243-2 a set voltage range and/or set voltage level. More specifically, the second power die 245-2 includes a plurality of wires and a plurality of capacitors to assist in keeping the power supply voltage VDD within a set voltage range, and/or not exceed the set voltage range.

The base die 241, the first core die group 243-1, the first power die 245-1, the second core die group 243-2, and the second power die 245-2 are connected using through-vias and transmit and receive signals using the through-vias. The signals transmitted and received by each of the base die 241, the first core die group 243-1, the first power die 245-1, the second core die group 243-2, and the second power die 245-2 using the through-vias include data, commands, addresses, and the like.

The first core die group 243-1, the first power die 245-1, the second core die group 243-2, and the second power die 245-2 are supplied with the power supply voltage VDD using the through-via, for example, the through-via 251-1 or the first transmission circuit 247-1, and are connected to a ground voltage VSS of the base die 241 using the through-via, for example, the through-via 251-2 or the second transmission circuit 247-2.

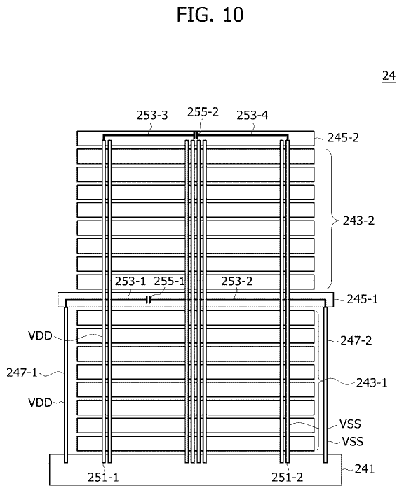

FIG. 10 illustrates a first power die 245-1 and a second power die 245-2 included in a memory device according to an embodiment of the present disclosure, for example, as illustrated in FIG. 9.

As illustrated in FIG. 10, the first power die 245-1 includes a first wire 253-1, a second wire 253-2, and a first capacitor 255-1. The first wire 253-1 is electrically connected to the first transmission circuit 247-1 through which the power supply voltage VDD of the base die 241 is supplied. The second wire 253-2 is electrically connected to the second transmission circuit 247-2 to which the ground voltage VSS of the base die 241 is connected. The first capacitor 255-1 is electrically connected between the first wire 253-1 and the second wire 253-2. The first capacitor 255-1 is electrically connected to the first transmission circuit 247-1 through which the power supply voltage VDD is supplied through the first wire 253-1, and is electrically connected to the second transmission circuit 247-2 to which the ground voltage VSS is connected through the second wire 253-2 to operate as a coupling device. The first capacitor 255-1 prevents or mitigates a voltage level of the power supply voltage VDD from rapidly fluctuating to maintain the voltage level of the power supply voltage VDD stably. In an embodiment, the first capacitor 255-1 prevents or mitigates a voltage level of the power supply voltage VDD from rapidly fluctuating to maintain the voltage level of the power supply voltage VDD within a set voltage range, and/or not exceed the set voltage range.

As illustrated in FIG. 10, the second power die 245-2 includes a third wire 253-3, a fourth wire 253-4, and a second capacitor 255-2. The third wire 253-3 is electrically connected to the first through-via 251-1 through which the power supply voltage VDD is supplied. The fourth wire 253-4 is electrically connected to the second through-via 251-2 to which the ground voltage VSS of the base die 241 is connected. The second capacitor 255-2 is electrically connected between the third wire 253-1 and the fourth wire 253-2. The second capacitor 255-2 is electrically connected to the first through-via 251-1 through which the power supply voltage VDD is supplied through the third wire 253-3, and is electrically connected to the second through-via 251-2 to which the ground voltage VSS is connected through the fourth wire 253-4 to operate as a coupling deice. The second capacitor 255-2 prevents or mitigates a voltage level of the power supply voltage VDD from rapidly fluctuating to maintain the voltage level of the power supply voltage VDD stably. In an embodiment, the second capacitor 255-2 prevents or mitigates a voltage level of the power supply voltage VDD from rapidly fluctuating to maintain the voltage level of the power supply voltage VDD within a set voltage range, and/or not exceed the set voltage range.

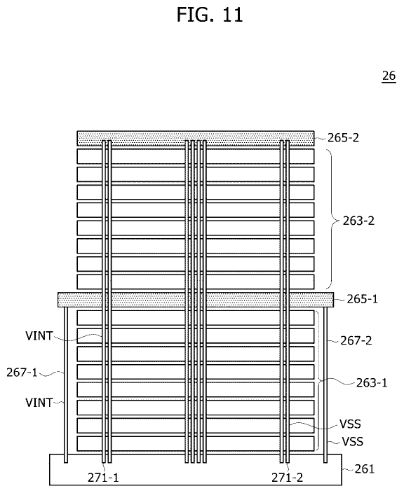

FIG. 11 illustrates a memory device 26 according to an embodiment of the present disclosure.

As illustrated in FIG. 11, the memory device 26 includes a base die 261, a first core die group 263-1, a first power die 265-1, a second core die group 263-2, a second power die 265-2, a first transmission circuit 267-1, and a second transmission circuit 267-2. The first core die group 263-1 is stacked over the base die 261, the first power die 265-1 is stacked over the first core die group 263-1, the second core die group 263-2 is stacked over the first power die 265-1, and the second power die 265-2 is stacked over the second core die group 263-2. The first power die 265-1 is positioned between the first core die group 263-1 and the second core die group 263-2. The first transmission circuit 267-1 electrically connects the base die 261 and the first power die 265-1, and the second transmission circuit 267-2 electrically connects the base die 261 and the first power die 265-1.

Each core die included in the first core die group 263-1 exchanges data with a processor, for example, a processor 59 in FIG. 21 under control of the base die 261. Each of the core dies included in the first core die group 263-1 includes a memory cell array that stores data. The data stored in the memory cell array of each of the core dies included in the first core die group 263-1 is transmitted to the processor under the control of the base die 261. The data transmitted from the processor is stored in the memory cell array of each of the core dies included in the first core die group 263-1 under the control of the base die 261.

The first power die 265-1 stabilizes an internal voltage VINT supplied to the first core die group 263-1 and the second core die group 263-2. More specifically, the first power die 265-1 includes a plurality of wires and a plurality of capacitors to stabilize the internal voltage VINT. For example, the first power die 265-1 maintains an internal voltage VINT supplied to the first core die group 263-1 and the second core die group 263-2 a set voltage range and/or set voltage level. More specifically, the first power die 265-1 includes a plurality of wires and a plurality of capacitors to assist in keeping the internal voltage VINT within a set voltage range, and/or not exceed the set voltage range.

Each core die included in the second core die group 263-2 exchanges data with the processor under the control of the base die 261. Each of the core dies included in the second core die group 263-2 includes a memory cell array that stores data. The data stored in the memory cell array of each of the core dies included in the second core die group 263-2 is transmitted to the processor under the control of the base die 261. The data transmitted from the processor is stored in the memory cell array of each of the core dies included in the second core die group 263-2 under the control of the base die 261.

The second power die 265-2 stabilizes the internal voltage VINT supplied to the first core die group 263-1 and the second core die group 263-2. More specifically, the second power die 265-2 includes a plurality of wires and a plurality of capacitors to stabilize the internal voltage VINT. For example, the second power die 265-2 maintains the internal voltage VINT supplied to the first core die group 263-1 and the second core die group 263-2 a set voltage range and/or set voltage level. More specifically, the second power die 265-2 includes a plurality of wires and a plurality of capacitors to assist in keeping the internal voltage VINT within a set voltage range, and/or not exceed the set voltage range.

The base die 261, the first core die group 263-1, the first power die 265-1, the second core die group 263-2, and the second power die 265-2 are connected using through-vias and transmit and receive signals using the through-vias. The signals transmitted and received by each of the base die 261, the first core die group 263-1, the first power die 265-1, the second core die group 263-2, and the second power die 265-2 using the through-vias include data, commands, addresses, and the like.

The first core die group 263-1, the first power die 265-1, the second core die group 263-2, and the second power die 265-2 are supplied with the internal voltage VINT using the through-via, for example, through-via 271-1 or the first transmission circuit 267-1, and are connected to a ground voltage VSS of the base die 261 using the through-via, for example, through-via 271-2 or the second transmission circuit 267-2.

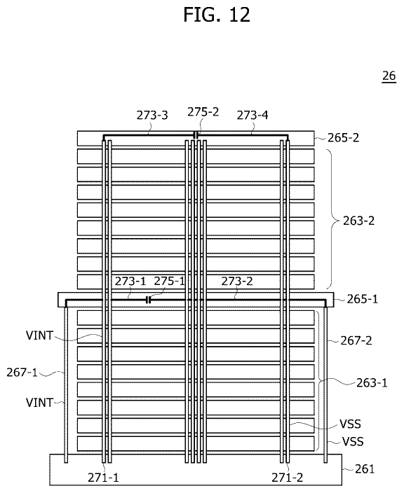

FIG. 12 illustrates a first power die 265-1 and a second power die 265-2 included in a memory device according to an embodiment of the present disclosure, for example, as illustrated in FIG. 11.

As illustrated in FIG. 12, the first power die 265-1 includes a first wire 273-1, a second wire 273-2, and a first capacitor 275-1. The first wire 273-1 is electrically connected to the first transmission circuit 267-1 through which the internal voltage VINT of the base die 261 is supplied. The second wire 273-2 is electrically connected to the second transmission circuit 267-2 to which the ground voltage VSS of the base die 261 is connected. The first capacitor 275-1 is electrically connected between the first wire 273-1 and the second wire 273-2. The first capacitor 275-1 is electrically connected to the first transmission circuit 267-1 through which the internal voltage VINT is supplied through the first wire 273-1, and is electrically connected to the second transmission circuit 267-2 to which the ground voltage VSS is connected through the second wire 273-2 to operate as a coupling device. The first capacitor 275-1 prevents or mitigates a voltage level of the internal voltage VINT from rapidly fluctuating to maintain the voltage level of the internal voltage VINT stably. In an embodiment, the first capacitor 275-1 prevents or mitigates a voltage level of the internal voltage VINT from rapidly fluctuating to maintain the voltage level of the internal voltage VINT within a set voltage range, and/or not exceed the set voltage range.

As illustrated in FIG. 12, the second power die 265-2 includes a third wire 273-3, a fourth wire 273-4, and a second capacitor 275-2. The third wire 273-3 is electrically connected to the first through-via 271-1 through which the internal voltage VINT is supplied. The fourth wire 273-4 is electrically connected to the second through-via 271-2 to which the ground voltage VSS of the base die 261 is connected. The second capacitor 275-2 is electrically connected between the third wire 273-3 and the fourth wire 273-4. The second capacitor 275-2 is electrically connected to the first through-via 271-1 through which the internal voltage VINT is supplied through the third wire 273-3, and is electrically connected to the second through-via 271-2 to which the ground voltage VSS is connected through the fourth wire 273-4 to operate as a coupling device. The second capacitor 275-2 prevents or mitigates a voltage level of the internal voltage VINT from rapidly fluctuating to maintain the voltage level of the internal voltage VINT stably. In an embodiment, the second capacitor 275-2 prevents or mitigates a voltage level of the internal voltage VINT from rapidly fluctuating to maintain the voltage level of the internal voltage VINT within a set voltage range, and/or not exceed the set voltage range.

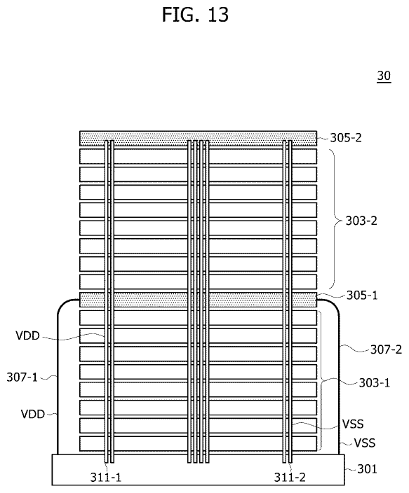

FIG. 13 illustrates a memory device 30 according to an embodiment of the present disclosure.

As illustrated in FIG. 13, the memory device 30 includes a base die 301, a first core die group 303-1, a first power die 305-1, a second core die group 303-2, a second power die 305-2, a first bonding wire 307-1, and a second bonding wire 307-2. The first core die group 303-1 is stacked over the base die 301, the first power die 305-1 is stacked over the first core die group 303-1, the second core die group 303-2 is stacked over the first power die 305-1, and the second power die 305-2 is stacked over the second core die group 303-2. The first power die 305-1 is positioned between the first core die group 303-1 and the second core die group 303-2. The first bonding wire 307-1 electrically connects the base die 301 and the first power die 305-1, and the second bonding wire 307-2 electrically connects the base die 301 and the first power die 305-1. The first bonding wire 307-1 and the second bonding wire 307-2 include a conductive material to which voltage can be supplied or electrically connected.

Each core die included in the first core die group 303-1 exchanges data with a processor, for example, a processor 59 in FIG. 21 under control of the base die 301. Each of the core dies included in the first core die group 303-1 includes a memory cell array that stores data. The data stored in the memory cell array of each of the core dies included in the first core die group 303-1 is transmitted to the processor under the control of the base die 301. The data transmitted from the processor is stored in the memory cell array of each of the core dies included in the first core die group 303-1 under the control of the base die 301.

The first power die 305-1 stabilizes a power supply voltage VDD supplied to the first core die group 303-1 and the second core die group 303-2. More specifically, the first power die 305-1 includes a plurality of wires and a plurality of capacitors to stabilize the power supply voltage VDD. For example, the first power die 305-1 maintains the power supply voltage VDD supplied to the first core die group 303-1 and the second core die group 303-2 a set voltage range and/or set voltage level. More specifically, the first power die 305-1 includes a plurality of wires and a plurality of capacitors to assist in keeping the power supply voltage VDD within a set voltage range, and/or not exceed the set voltage range.

Each core die included in the second core die group 303-2 exchanges data with the processor under the control of the base die 301. Each of the core dies included in the second core die group 303-2 includes a memory cell array that stores data. The data stored in the memory cell array of each of the core dies included in the second core die group 303-2 is transmitted to the processor under the control of the base die 301. The data transmitted from the processor is stored in the memory cell array of each of the core dies included in the second core die group 303-2 under the control of the base die 301.

The second power die 305-2 stabilizes the power supply voltage VDD supplied to the first core die group 303-1 and the second core die group 303-2. More specifically, the second power die 305-2 includes a plurality of wires and a plurality of capacitors to stabilize the power supply voltage VDD. For example, the second power die 305-2 maintains the power supply voltage VDD supplied to the first core die group 303-1 and the second core die group 303-2 a set voltage range and/or set voltage level. More specifically, the second power die 305-2 includes a plurality of wires and a plurality of capacitors to assist in keeping the power supply voltage VDD within a set voltage range, and/or not exceed the set voltage range.

The base die 301, the first core die group 303-1, the first power die 305-1, the second core die group 303-2, and the second power die 305-2 are connected using through-vias and transmit and receive signals using the through-vias. The signals transmitted and received by each of the base die 301, the first core die group 303-1, the first power die 305-1, the second core die group 303-2, and the second power die 305-2 using the through-vias include data, commands, addresses, and the like. Each of the base die 301, the first core die group 303-1, the first power die 305-1, the second core die group 303-2, and the second power die 305-2 receives the power supply voltage VDD using the through-vias or the first bonding wire 307-1.

The first core die group 303-1, the first power die 305-1, the second core die group 303-2, and the second power die 305-2 are supplied with the power supply voltage VDD using the through-vias, for example, through-via 311-1 or the first bonding wire 307-1 and are connected to a ground voltage VSS of the base die 301 using the through-via, for example, through-via 311-2 or the second bonding wire 307-2.

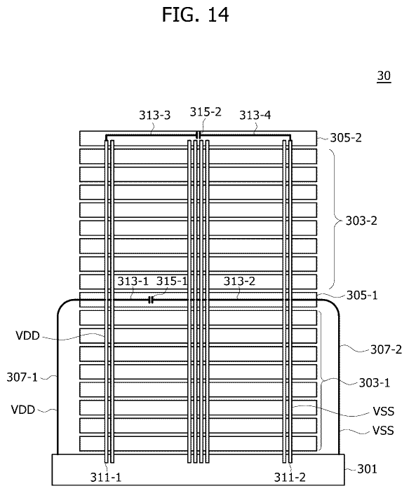

FIG. 14 illustrates a first power die 305-1 and a second power die 305-2 included in a memory device 30, for example as shown in FIG. 13.

As illustrated in FIG. 14, the first power die 305-1 includes a first wire 313-1, a second wire 313-2, and a first capacitor 315-1. The first wire 313-1 is electrically connected to the first bonding wire 307-1 through which the power supply voltage VDD of the base die 301 is supplied. The second wire 313-2 is electrically connected to the second bonding wire 307-2 to which the ground voltage VSS of the base die 301 is connected. The first capacitor 315-1 is electrically connected between the first wire 313-1 and the second wire 313-2. The first capacitor 315-1 is electrically connected to the first bonding wire 307-1 through which the power supply voltage VDD is supplied through the first wire 313-1, and is electrically connected to the second bonding wire 307-2 to which the ground voltage VSS is connected through the second wire 313-2 to operate as a coupling device. The first capacitor 315-1 prevents or mitigates a voltage level of the power supply voltage VDD from rapidly fluctuating to maintain the voltage level of the power supply voltage VDD stably. In an embodiment, the first capacitor 315-1 prevents or mitigates a voltage level of the power supply voltage VDD from rapidly fluctuating to maintain the voltage level of the power supply voltage VDD within a set voltage range, and/or not exceed the set voltage range.

As illustrated in FIG. 14, the second power die 305-2 includes a third wire 313-3, a fourth wire 313-4, and a second capacitor 315-2. The third wire 313-3 is electrically connected to the first through-via 311-1 through which the power supply voltage VDD of the base die 301 is supplied. The fourth wire 313-4 is electrically connected to the second through-via 311-2 to which the ground voltage VSS of the base die 301 is connected. The second capacitor 315-2 is electrically connected between the third wire 313-1 and the fourth wire 313-2. The second capacitor 315-2 is electrically connected to the first through-via 311-1 through which the power supply voltage VDD is supplied through the third wire 313-3, and is electrically connected to the second through-via 311-2 to which the ground voltage VSS is connected through the fourth wire 313-4 to operate as a coupling device. The second capacitor 315-2 prevents or mitigates a voltage level of the power supply voltage VDD from rapidly fluctuating to maintain the voltage level of the power supply voltage VDD stably. In an embodiment, the second capacitor 315-2 prevents or mitigates a voltage level of the power supply voltage VDD from rapidly fluctuating to maintain the voltage level of the power supply voltage VDD within a set voltage range, and/or not exceed the set voltage range.

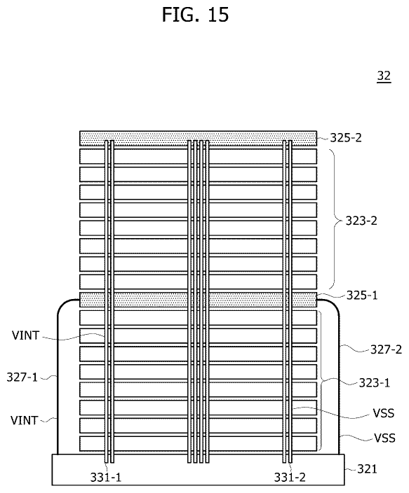

FIG. 15 illustrates a memory device 32 according to an embodiment of the present disclosure.

As illustrated in FIG. 15, the memory device 32 includes a base die 321, a first core die group 323-1, a first power die 325-1, a second core die group 323-2, a second power die 325-2, a first bonding wire 327-1, and a second bonding wire 327-2. The first core die group 323-1 is stacked over the base die 321, the first power die 325-1 is stacked over the first core die group 323-1, the second core die group 323-2 is stacked over the first power die 325-1, and the second power die 325-2 is stacked over the second core die group 323-2. The first power die 325-1 is positioned between the first core die group 323-1 and the second core die group 323-2. The first bonding wire 327-1 electrically connects the base die 321 and the first power die 325-1, and the second bonding wire 327-2 electrically connects the base die 321 and the first power die 325-1.

Each core die included in the first core die group 323-1 exchanges data with a processor, for example, a processor 59 in FIG. 21 under control of the base die 321. Each of the core dies included in the first core die group 323-1 includes a memory cell array that stores data. The data stored in the memory cell array of each of the core dies included in the first core die group 323-1 is transmitted to the processor under the control of the base die 321. The data transmitted from the processor is stored in the memory cell array of each of the core dies included in the first core die group 323-1 under the control of the base die 321.

The first power die 325-1 stabilizes an internal voltage VINT supplied to the first core die group 323-1 and the second core die group 323-2. More specifically, the first power die 325-1 includes a plurality of wires and a plurality of capacitors to stabilize the internal voltage VINT. For example, the first power die 325-1 maintains an internal voltage VINT supplied to the first core die group 323-1 and the second core die group 323-2 a set voltage range and/or set voltage level. More specifically, the first power die 325-1 includes a plurality of wires and a plurality of capacitors to assist in keeping the internal voltage VINT within a set voltage range, and/or not exceed the set voltage range.

Each core die included in the second core die group 323-2 exchanges data with the processor under the control of the base die 321. Each of the core dies included in the second core die group 323-2 includes a memory cell array that stores data. The data stored in the memory cell array of each of the core dies included in the second core die group 323-2 is transmitted to the processor under the control of the base die 321. The data transmitted from the processor is stored in the memory cell array of each of the core dies included in the second core die group 323-2 under the control of the base die 321.

The second power die 325-2 stabilizes the internal voltage VINT supplied to the first core die group 323-1 and the second core die group 323-2. More specifically, the second power die 325-2 includes a plurality of wires and a plurality of capacitors to stabilize the internal voltage VINT. For example, the second power die 325-2 maintains the internal voltage VINT supplied to the first core die group 323-1 and the second core die group 323-2 a set voltage range and/or set voltage level. More specifically, the second power die 325-2 includes a plurality of wires and a plurality of capacitors to assist in keeping the internal voltage VINT within a set voltage range, and/or not exceed the set voltage range.

The base die 321, the first core die group 323-1, the first power die 325-1, the second core die group 323-2, and the second power die 325-2 are connected using through-vias and transmit and receive signals using the through-vias. The signals transmitted and received by each of the base die 321, the first core die group 323-1, the first power die 325-1, the second core die group 323-2, and the second power die 325-2 using the through-vias include data, commands, addresses, and the like. Each of the base die 321, the first core die group 323-1, the first power die 325-1, the second core die group 323-2, and the second power die 325-2 receives the internal voltage VINT using the through-vias or the first bonding wire 327-1.

The first core die group 323-1, the first power die 325-1, the second core die group 323-2, and the second power die 325-2 are supplied with the internal voltage VINT using the through-via, for example, through-via 331-1 or the first bonding wire 327-1, and are connected to a ground voltage VSS of the base die 321 using the through-via, for example, through-via 331-2 or the second bonding wire 327-2.

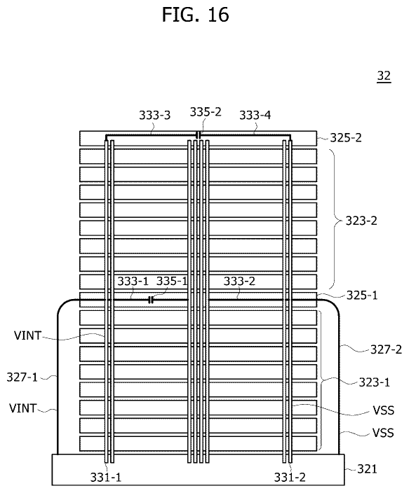

FIG. 16 illustrates a first power die 325-1 and a second power die 325-2 included in a memory device according to an embodiment of the present disclosure, for example, as illustrated in FIG. 15.

As illustrated in FIG. 16, the first power die 325-1 includes a first wire 333-1, a second wire 333-2, and a first capacitor 335-1. The first wire 333-1 is electrically connected to the first bonding wire 327-1 through which the internal voltage VINT of the base die 321 is supplied. The second wire 333-2 is electrically connected to the second bonding wire 327-2 to which the ground voltage VSS of the base die 321 is connected. The first capacitor 335-1 is electrically connected between the first wire 333-1 and the second wire 333-2. The first capacitor 335-1 is electrically connected to the first bonding wire 327-1 through which the internal voltage VINT is supplied through the first wire 333-1, and is electrically connected to the second bonding wire 327-2 to which the ground voltage VSS is connected through the second wire 333-2 to operate as a coupling device. The first capacitor 335-1 prevents or mitigates a voltage level of the internal voltage VINT from rapidly fluctuating to maintain the voltage level of the internal voltage VINT stably. In an embodiment, the first capacitor 335-1 prevents or mitigates a voltage level of the internal voltage VINT from rapidly fluctuating to maintain the voltage level of the internal voltage VINT within a set voltage range, and/or not exceed the set voltage range.

As illustrated in FIG. 16, the second power die 325-2 includes a third wire 333-3, a fourth wire 333-4, and a second capacitor 335-2. The third wire 333-3 is electrically connected to the first through-via 331-1 through which the internal voltage VINT of the base die 321 is supplied. The fourth wire 333-4 is electrically connected to the second through-via 331-2 to which the ground voltage VSS of the base die 321 is connected. The second capacitor 335-2 is electrically connected between the third wire 333-3 and the fourth wire 333-4. The second capacitor 335-2 is electrically connected to the first through-via 331-1 through which the internal voltage VINT is supplied through the third wire 333-3, and is electrically connected to the second through-via 331-2 to which the ground voltage VSS is connected through the fourth wire 333-4 to operate as a coupling device. The second capacitor 335-2 prevents or mitigates a voltage level of the internal voltage VINT from rapidly fluctuating to maintain the voltage level of the internal voltage VINT stably. In an embodiment, the second capacitor 335-2 prevents or mitigates a voltage level of the internal voltage VINT from rapidly fluctuating to maintain the voltage level of the internal voltage VINT within a set voltage range, and/or not exceed the set voltage range.

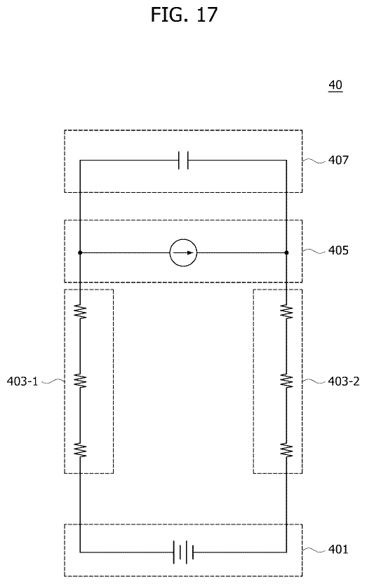

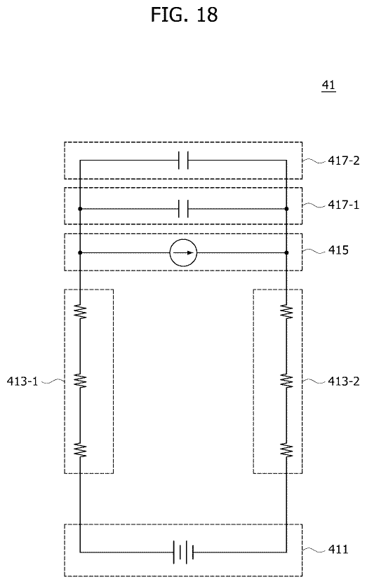

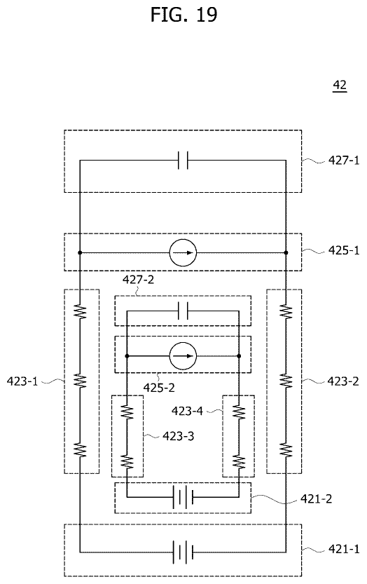

FIG. 17 to FIG. 19 illustrate equivalent circuits 40, 41, and 42 of memory devices according to embodiments of the present disclosure.

As illustrated in FIG. 17, the equivalent circuit 40 includes a power supply circuit 401, a first resistor circuit 403-1, a second resistor circuit 403-2, a core die circuit 405, and a power die circuit 407.

The equivalent circuit 40 corresponds to the memory device 10 illustrated in FIG. 1 and FIG. 2. Referring to FIG. 1, FIG. 2, and FIG. 17, the power supply circuit 401 corresponds to the substrate 100 from which the power supply voltage VDD is supplied, the first resistor circuit 403-1 corresponds to the through-via 111-1 through which the power supply voltage VDD is supplied, the second resistor circuit 403-2 corresponds to the through-via 111-2 to which the ground voltage VSS is connected, the core die circuit 405 corresponds to a core die that receives and uses the power supply voltage VDD among the core dies 103, and the power die circuit 407 corresponds to the power die 105.

The equivalent circuit 40 corresponds to the memory device 12 illustrated in FIG. 3 and FIG. 4. Referring to FIG. 3, FIG. 4, and FIG. 17, the power supply circuit 401 corresponds to the base die 121 or one of the core dies that generates the internal voltage VINT, the first resistor circuit 403-1 corresponds to the through-via 131-1 through which the internal voltage VINT is supplied, the second resistor circuit 403-2 corresponds to the through-via 131-2 to which the ground voltage VSS is connected, the core die circuit 405 corresponds to a core die that receives and uses the internal voltage VINT among the core dies 123, and the power die circuit 407 corresponds to the power die 125.

As illustrated in FIG. 18, the equivalent circuit 41 includes a power supply circuit 411, a first resistor circuit 413-1, a second resistor circuit 413-2, a core die circuit 415, a first power die circuit 417-1. and a second power die circuit 417-2.

The equivalent circuit 41 corresponds to the memory device 20 illustrated in FIG. 5 and FIG. 6. Referring to FIG. 5, FIG. 6, and FIG. 18, the power supply circuit 411 corresponds to the base die 201 from which the power supply voltage VDD is supplied, the first resistor circuit 413-1 corresponds to the through-via 211-1 through which the power supply voltage VDD is supplied, the second resistor circuit 413-2 corresponds to the through-via 211-2 to which the ground voltage VSS is connected, the core die circuit 415 corresponds to a core die that receives and uses the power supply voltage VDD among the core dies included in the first core die group 203-1 and the second core die group 203-2, the first power die circuit 417-1 corresponds to the first power die 205-1, and the second power die circuit 417-2 corresponds to the second power die 205-2.

The equivalent circuit 41 corresponds to the memory device 22 illustrated in FIG. 7 and FIG. 8. Referring to FIG. 7, FIG. 8, and FIG. 18, the power supply circuit 411 corresponds to the base die 221 from which the internal voltage VINT is supplied, the first resistor circuit 413-1 corresponds to the through-via 231-1 through which the internal voltage VINT is supplied, the second resistor circuit 413-2 corresponds to the through-via 231-2 to which the ground voltage VSS is connected, the core die circuit 415 corresponds to a core die that receives and uses the internal voltage VINT among the core dies included in the first core die group 223-1 and the second core die group 223-2, the first power die circuit 417-1 corresponds to the first power die 225-1, and the second power die circuit 417-2 corresponds to the second power die 225-2.

As illustrated in FIG. 19, the equivalent circuit 42 includes a first power supply circuit 421-1, a second power supply circuit 421-2, a first resistor circuit 423-1, a second resistor circuit 423-2, a third resistor circuit 423-3, a fourth resistor circuit 423-4, a first core die circuit 425-1, a second core die circuit 425-2, a first power die circuit 427-1, and a second power die circuit 427-2.

The equivalent circuit 42 corresponds to the memory device 24 illustrated in FIG. 9 and FIG. 10. Referring to FIG. 9, FIG. 10, and FIG. 19, each of the first power supply circuit 421-1 and the second power supply circuit 421-2 corresponds to the base die 241 from which the power supply voltage VDD is supplied, the first resistor circuit 423-1 corresponds to the through-via 251-1 through which the power supply voltage VDD is supplied, the second resistor circuit 423-2 corresponds to the through-via 251-2 to which the ground voltage VSS is connected, the third resistor circuit 423-3 corresponds to the first transmission circuit 247-1 through which the power supply voltage VDD is supplied, the fourth resistor circuit 423-4 corresponds to the second transmission circuit 247-2 to which the ground voltage VSS is connected, each of the first core die circuit 425-1 and the second core die circuit 425-2 corresponds to a core die that receives and uses the power supply voltage VDD among the core dies included in the first core die group 243-1 and the second core die group 243-2, the first power die circuit 427-1 corresponds to the second power die 245-2, and the second power die circuit 427-2 corresponds to the first power die 245-1.

The equivalent circuit 42 corresponds to the memory device 26 illustrated in FIG. 11 and FIG. 12. Referring to FIG. 11, FIG. 12, and FIG. 19, each of the first power supply circuit 421-1 and the second power supply circuit 421-2 corresponds to the base die 261 from which the internal voltage VINT is supplied, the first resistor circuit 423-1 corresponds to the through-via 271-1 through which the internal voltage VINT is supplied, the second resistor circuit 423-2 corresponds to the through-via 271-2 to which the ground voltage VSS is connected, the third resistor circuit 423-3 corresponds to the first transmission circuit 267-1 through which the internal voltage VINT is supplied, the fourth resistor circuit 423-4 corresponds to the second transmission circuit 267-2 to which the ground voltage VSS is connected, each of the first core die circuit 425-1 and the second core die circuit 425-2 corresponds to a core die that receives and uses the internal voltage VINT among the core dies included in the first core die group 263-1 and the second core die group 263-2, the first power die circuit 427-1 corresponds to the second power die 265-2, and the second power die circuit 427-2 corresponds to the first power die 265-1.

The equivalent circuit 42 corresponds to the memory device 30 illustrated in FIG. 13 and FIG. 14. Referring to FIG. 13, FIG. 14, and FIG. 19, each of the first power supply circuit 421-1 and the second power supply circuit 421-2 corresponds to the base die 301 from which the power supply voltage VDD is supplied, the first resistor circuit 423-1 corresponds to the through-via 311-1 through which the power supply voltage VDD is supplied, the second resistor circuit 423-2 corresponds to the through-via 311-2 to which the ground voltage VSS is connected, the third resistor circuit 423-3 corresponds to the first bonding wire 307-1 through which the power supply voltage VDD is supplied, the fourth resistor circuit 423-4 corresponds to the second bonding wire 307-2 to which the ground voltage VSS is connected, each of the first core die circuit 425-1 and the second core die circuit 425-2 corresponds to a core die that receives and uses the power supply voltage VDD among the core dies included in the first core die group 303-1 and the second core die group 303-2, the first power die circuit 427-1 corresponds to the second power die 305-2, and the second power die circuit 427-2 corresponds to the first power die 305-1.

The equivalent circuit 42 corresponds to the memory device 32 illustrated in FIG. 15 and FIG. 16. Referring to FIG. 15, FIG. 16, and FIG. 19, each of the first power supply circuit 421-1 and the second power supply circuit 421-2 corresponds to the base die 321 from which the internal voltage VINT is supplied, the first resistor circuit 423-1 corresponds to the through-via 331-1 through which the internal voltage VINT is supplied, the second resistor circuit 423-2 corresponds to the through-via 331-2 to which the ground voltage VSS is connected, the third resistor circuit 423-3 corresponds to the first bonding wire 327-1 through which the internal voltage VINT is supplied, the fourth resistor circuit 423-4 corresponds to the second bonding wire 327-2 to which the ground voltage VSS is connected, each of the first core die circuit 425-1 and the second core die circuit 425-2 corresponds to a core die that receives and uses the internal voltage VINT among the core dies included in the first core die group 323-1 and the second core die group 323-2, the first power die circuit 427-1 corresponds to the second power die 325-2, and the second power die circuit 427-2 corresponds to the first power die 325-1.

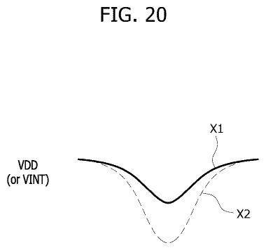

FIG. 20 illustrates waveforms of a power supply voltage VDD and an internal voltage VINT stabilized by power dies provided in a memory device according to an embodiment of the present disclosure.

Voltage level fluctuation X1 of the power supply voltage VDD supplied through the through-via 111-1 when the power die 105 is provided in the memory device 10 illustrated in FIG. 1 and FIG. 2 is maintained stably compared to the voltage level fluctuation X2 of the power voltage VDD when the power die 105 is not provided. For example, the voltage level fluctuation X1 of the power supply voltage VDD supplied through the through-via 111-1 when the power die 105 is provided in the memory device 10 illustrated in FIG. 1 and FIG. 2 is maintained within a set voltage range and/or does not exceed an upper voltage limit as compared to the voltage level fluctuation X2 of the power voltage VDD when the power die 105 is not provided. For example, the voltage level fluctuation X2 of the power voltage VDD is shown as exceeding the upper voltage limit and/or is not maintained within a set voltage range. Whereas X1, when compared to voltage level fluctuation X2, is shown as not exceeding the upper voltage limit and/or is maintained within a set voltage range (e.g., maintained within set upper and lower voltage levels that are respectively less than the upper and lower voltage levels of voltage level fluctuation X2). In an embodiment, the voltage level fluctuation X2 may represent the upper voltage limit that is not exceeded by the voltage level fluctuation X1. As such, as shown in FIG. 20, the voltage level fluctuation X1 remains less than a set voltage level so that the voltage level fluctuation X1 does not exceed any of the voltage levels represented by the voltage level fluctuation X2.

The voltage level fluctuation X1 of the internal voltage VINT supplied through the through-via 131-1 when the power die 125 is provided in the memory device 12 illustrated in FIG. 3 and FIG. 4 is maintained stably compared to the voltage level fluctuation X2 of the internal voltage VINT when the power die 125 is not provided. For example, the voltage level fluctuation X1 of the internal voltage VINT supplied through the through-via 131-1 when the power die 125 is provided in the memory device 12 illustrated in FIG. 3 and FIG. 4 is maintained within a set voltage range and/or remains less than a set voltage level as compared to the voltage level fluctuation X2 of the internal voltage VINT when the power die 125 is not provided.

The voltage level fluctuation X1 of the power voltage VDD supplied through the through-via 211-1 when the first power die 205-1 and the second power die 205-2 are provided in the memory device 20 illustrated in FIG. 5 and FIG. 6 is maintained stably compared to the voltage level fluctuation X2 of the power voltage VDD when the first power die 205-1 and the second power die 205-2 are not provided. For example, the voltage level fluctuation X1 of the power voltage VDD supplied through the through-via 211-1 when the first power die 205-1 and the second power die 205-2 are provided in the memory device 20 illustrated in FIG. 5 and FIG. 6 is maintained within a set voltage range and/or remains less than a set voltage level as compared to the voltage level fluctuation X2 of the power voltage VDD when the first power die 205-1 and the second power die 205-2 are not provided.

The voltage level fluctuation X1 of the internal voltage VINT supplied through the through-via 231-1 when the first power die 225-1 and the second power die 225-2 are provided in the memory device 22 illustrated in FIG. 7 and FIG. 8 is maintained stably compared to the voltage level fluctuation X2 of the internal voltage VINT when the first power die 225-1 and the second power die 225-2 are not provided. For example, the voltage level fluctuation X1 of the internal voltage VINT supplied through the through-via 231-1 when the first power die 225-1 and the second power die 225-2 are provided in the memory device 22 illustrated in FIG. 7 and FIG. 8 is maintained within a set voltage range and/or remains less than a set voltage level as compared to the voltage level fluctuation X2 of the internal voltage VINT when the first power die 225-1 and the second power die 225-2 are not provided.

The voltage level fluctuation X1 of the power voltage VDD supplied through the through-via 251-1 when the first power die 245-1 and the second power die 245-2 are provided in the memory device 24 illustrated in FIG. 9 and FIG. 10 is maintained stably compared to the voltage level fluctuation X2 of the power voltage VDD when the first power die 245-1 and the second power die 245-2 are not provided. For example, the voltage level fluctuation X1 of the power voltage VDD supplied through the through-via 251-1 when the first power die 245-1 and the second power die 245-2 are provided in the memory device 24 illustrated in FIG. 9 and FIG. 10 is maintained within a set voltage range and/or remains less than a set voltage level as compared to the voltage level fluctuation X2 of the power voltage VDD when the first power die 245-1 and the second power die 245-2 are not provided.

The voltage level fluctuation X1 of the internal voltage VINT supplied through the through-via 271-1 and the transmission circuit 267-1 when the first power die 265-1 and the second power die 265-2 are provided in the memory device 26 illustrated in FIG. 11 and FIG. 12 is maintained stably compared to the voltage level fluctuation X2 of the internal voltage VINT when the first power die 265-1 and the second power die 265-2 are not provided. For example, the voltage level fluctuation X1 of the internal voltage VINT supplied through the through-via 271-1 and the transmission circuit 267-1 when the first power die 265-1 and the second power die 265-2 are provided in the memory device 26 illustrated in FIG. 11 and FIG. 12 is maintained within a set voltage range and/or remains less than a set voltage level as compared to the voltage level fluctuation X2 of the internal voltage VINT when the first power die 265-1 and the second power die 265-2 are not provided.

The voltage level fluctuation X1 of the power voltage VDD supplied through the through-via 311-1 and the first bonding wire 307-1 when the first power die 305-1 and the second power die 305-2 are provided in the memory device 30 illustrated in FIG. 13 and FIG. 14 is maintained stably compared to the voltage level fluctuation X2 of the power voltage VDD when the first power die 305-1 and the second power die 305-2 are not provided. For example, the voltage level fluctuation X1 of the power voltage VDD supplied through the through-via 311-1 and the first bonding wire 307-1 when the first power die 305-1 and the second power die 305-2 are provided in the memory device 30 illustrated in FIG. 13 and FIG. 14 is maintained within a set voltage range and/or remains less than a set voltage level as compared to the voltage level fluctuation X2 of the power voltage VDD when the first power die 305-1 and the second power die 305-2 are not provided.

The voltage level fluctuation X1 of the internal voltage VINT supplied through the through-via 331-1 and the first bonding wire 327-1 when the first power die 325-1 and the second power die 325-2 are provided in the memory device 32 illustrated in FIG. 15 and FIG. 16 is maintained stably compared to the voltage level fluctuation X2 of the internal voltage VINT when the first power die 325-1 and the second power die 325-2 are not provided. For example, the voltage level fluctuation X1 of the internal voltage VINT supplied through the through-via 331-1 and the first bonding wire 327-1 when the first power die 325-1 and the second power die 325-2 are provided in the memory device 32 illustrated in FIG. 15 and FIG. 16 is maintained within a set voltage range and/or remains less than a set voltage level as compared to the voltage level fluctuation X2 of the internal voltage VINT when the first power die 325-1 and the second power die 325-2 are not provided.

FIG. 21 illustrates a memory system 5 according to an embodiment of the present disclosure.

As illustrated in FIG. 21, the memory system 5 includes a printed circuit board (PCB) 51, a substrate 53, an interposer 55, a memory device 57, and a processor 59.

The printed circuit board 51 connects various electronic components to each other to form electronic circuits (not illustrated). The electronic circuits include the memory system 5. A copper (Cu) layer, a solder mask, and a silk screen, and so forth may be formed on the printed circuit board 51. The copper (Cu) layer forms a circuit path that transmits or transfers signals or power. In an embodiment, the solder mask prevents or mitigates damage to the circuit and protects specific regions where components are soldered. In an embodiment, the silk screen indicates location or information for the electronic components as characters or symbols printed on a surface of the printed circuit board 51.

The substrate 53 is disposed over the printed circuit board 51 with bump pads in between, for example, bump pads 511 and mechanically supports the interposer 55, the memory device 57, and the processor 59.

The interposer 55 is disposed over the substrate 53 with bump pads in between and includes wires connecting electronic components, for example, the memory device 57 and the processor 59, that have form factors or pin arrangements not matched or have different spacing. The interposer 55 converts signals for communication across different interfaces such as DDR, HBM, and PCIe.

The memory device 57 is disposed over the interposer 55 with micro-bump pads in between, for example, micro-bump pads 513. The memory device 57 stores data transmitted from the processor 59 or outputs the stored data to the processor 59 under control of the processor 59. The memory device 57 includes a base die 520 and a plurality of core dies 521-1 to 521-L, where “L” is an integer greater than 1. The core dies 521-1 to 521-L are stacked over the base die 520 with micro-bump pads in between. The base die 520 and the core dies 521-1 to 521-L are vertically connected to each other using through-vias and the micro-bump pads. The base die 520 controls efficient data transmission between the processor 59 and the core dies 521-1 to 521-L. The base die 520 receives input/output power voltage (voltage drain drain for IO also referred to as output stage drain power voltage) VDDQ as an operating voltage utilized during operation of internal circuits included in the base die 520. The base die 520 receives the input/output power voltage VDDQ from the printed circuit board 51 through the substrate 53 and the interposer 55. The input/output power voltage VDDQ is a voltage supplied to buffers that transmit data and is distinguished or different from the power supply voltage VDD. The core dies 521-1 to 521-L use a peripheral voltage VPERI as an operating voltage during operation of the internal circuits included in the core dies 521-1 to 521-L. The core dies 521-1 to 521-L generate the peripheral voltage VPERI from the input/output power voltage VDDQ received through the base die 520. The core dies 521-1 to 521-L generate the peripheral voltage VPERI at a lower voltage level than the input/output power voltage VDDQ and use the peripheral voltage VPERI as an operating voltage. Each of the core dies 521-1 to 521-L includes a plurality of channel regions, for example, eight channel regions or sixteen channel regions that operate independently. Each of the plurality of channel regions is allocated with a channel operating independently to receive or transmit data. The number L of core dies 521-1 to 521-L may be four, eight, twelve, sixteen, and so forth. For example, when each of the core dies 521-1 to 521-12 has eight channels, the core dies 521-1 to 521-4, the core dies 521-5 to 521-8, and the core dies 521-9 to 521-12 each include thirty-two channel regions, and transmit and receive data with the processor 19 in units of a rank including thirty two channels.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory device comprising:
a base die disposed over a substrate;
a plurality of core dies disposed over the base die; and
a power die disposed over the plurality of core dies,
wherein the base die, the plurality of core dies, and the power die are connected to each other using through-vias, and
wherein the power die comprises a coupling device that keeps a power supply voltage supplied through the through-vias within a set voltage range.

2. The memory device of claim 1, wherein the power supply voltage is supplied to each of the plurality of core dies from the substrate through the through-vias.

3. The memory device of claim 1, wherein the through-vias comprise:
a first through-via through which the power supply voltage is supplied; and
a second through-via to which a ground voltage is connected.

4. The memory device of claim 3, wherein the power die comprises:
a first wire connected to the first through-via;
a second wire connected to the second through-via; and
a capacitor that is connected between the first wire and the second wire and operates as a coupling device.

5. A memory device comprising:
a plurality of core dies disposed over a base die; and
a power die disposed over the plurality of core dies,
wherein the base die, the plurality of core dies, and the power die are connected to each other using through-vias, and
wherein the power die comprises a coupling device that keeps an internal voltage supplied through the through-vias within a set voltage range.

6. The memory device of claim 5, wherein one of the base die and the core dies generates the internal voltage to supply the internal voltage through the through-vias.

7. The memory device of claim 5, wherein the through-vias comprise:
a first through-via through which the internal voltage is supplied; and
a second through-via to which a ground voltage is connected.

8. The memory device of claim 7, wherein the power die comprises:
a first wire connected to the first through-via;
a second wire connected to the second through-via; and
a capacitor that is connected between the first wire and the second wire and operates as the coupling device.

9. A memory device comprising:
a first core die group disposed over a base die;
a first power die disposed over the first core die group;
a second core die group disposed over the first power die; and
a second power die disposed over the second core die group,
wherein the base die, the first core die group, the first power die, the second core die group, and the second power die are connected to each other using through-vias, and
wherein each of the first power die and the second power die comprises a coupling device that keeps a power supply voltage supplied through the through-vias.

10. The memory device of claim 9, wherein the power supply voltage is supplied to each core die included in the first core die group and the second core die group through the through-vias.

11. The memory device of claim 10, wherein the through-vias comprise:
a first through-via through which the power supply voltage is supplied; and
a second through-via to which a ground voltage is connected.

12. The memory device of claim 11, wherein the first power die comprises:
a first wire connected to the first through-via;
a second wire connected to the second through-via; and
a first capacitor connected between the first wire and the second wire.

13. The memory device of claim 12, wherein the second power die comprises:
a third wire connected to the first through-via;
a fourth wire connected to the second through-via; and
a second capacitor connected between the third wire and the fourth wire.

14. A memory device comprising:
a first core die group disposed over a base die;
a first power die disposed over the first core die group;
a second core die group disposed over the first power die; and
a second power die disposed over the second core die group,
wherein the base die, the first core die group, the first power die, the second core die group, and the second power die are connected to each other using through-vias, and
wherein each of the first power die and the second power die comprises a coupling device that keeps an internal voltage supplied through the through-vias within a set voltage range.

15. A memory device comprising:
a first core die group disposed over a base die;
a first power die disposed over the first core die group;
a second core die group disposed over the first power die;
a second power die disposed over the second core die group;
a first transmission circuit connected between the base die and the first power die to supply a power supply voltage; and
a second transmission circuit connected between the base die and the second power die to be connected to a ground voltage,
wherein the base die, the first core die group, the first power die, the second core die group, and the second power die are connected to each other using through-vias, and
wherein each of the first power die and the second power die comprises a coupling device that keeps the power supply voltage supplied through the through-vias within a set voltage range.

16. The memory device of claim 15, wherein the first power die comprises:
a first wire connected to the first transmission circuit;
a second wire connected to the second transmission circuit; and
a first capacitor connected between the first wire and the second wire.

17. The memory device of claim 15,
wherein the through-vias comprise:
a first through-via through which the power supply voltage is supplied; and
a second through-via to which a ground voltage is connected, and
wherein the second power die comprises:
a third wire connected to the first through-via;
a fourth wire connected to the second through-via; and
a second capacitor connected between the third wire and the fourth wire.

18. A memory device comprising:
a first core die group disposed over a base die;
a first power die disposed over the first core die group;
a second core die group disposed over the first power die;
a second power die disposed over the second core die group;
a first transmission circuit connected between the base die and the first power die to supply an internal voltage; and
a second transmission circuit connected between the base die and the second power die to be connected to a ground voltage,
wherein the base die, the first core die group, the first power die, the second core die group, and the second power die are connected to each other using through-vias, and
wherein each of the first power die and the second power die comprises a coupling device that keeps the internal voltage supplied through the through-vias or the first transmission circuit within a set voltage range.

19. A memory device comprising:
a first core die group disposed over a base die;
a first power die disposed over the first core die group;
a second core die group disposed over the first power die;
a second power die disposed over the second core die group;
a first bonding wire connected between the base die and the first power die to supply a power supply voltage; and
a second bonding wire connected between the base die and the second power die to be connected to a ground voltage,
wherein the base die, the first core die group, the first power die, the second core die group, and the second power die are connected to each other using through-vias, and
wherein each of the first power die and the second power die comprises a coupling device that keeps the power supply voltage supplied through the through-vias or the first transmission circuit within a set voltage range.

20. A memory device comprising:
a first core die group disposed over a base die;
a first power die disposed over the first core die group;
a second core die group disposed over the first power die;
a second power die disposed over the second core die group;
a first bonding wire connected between the base die and the first power die to supply an internal voltage; and
a second bonding wire connected between the base die and the second power die to be connected to a ground voltage,
wherein the base die, the first core die group, the first power die, the second core die group, and the second power die are connected to each other using through-vias, and
wherein each of the first power die and the second power die comprises a coupling device that keeps the internal voltage supplied through the through-vias or the first bonding wire within a set voltage range.

21. A memory system comprising a processor and a memory device disposed over an interposer,
wherein the memory device comprises:
a core die structure comprising a plurality of core dies stacked over a base die; and
at least one power die comprising a coupling device that keeps a power supply voltage or an internal voltage supplied to each of the plurality of core dies within a set voltage range.

22. The memory system of claim 21, wherein the power die is disposed over the plurality of core dies.

23. The memory system of claim 21, wherein the power die is disposed between the plurality of core dies.

24. The memory system of claim 21, wherein one of the base die and the plurality of core dies is configured to generate the internal voltage to supply the internal voltage to the power die using through-vias.

25. The memory device of claim 21, wherein the power supply voltage is supplied to each of the plurality of core dies using through-vias.
